(19) United States
(12) Patent Application Publication
(10) Pub. No.: US 2023/0184863 A1
(43) Pub. Date: Jun. 15, 2023

(54) METHOD FOR AUTOMATICALLY COMPENSATING EDDY CURRENTS IN A MAGNETIC RESONANCE APPARATUS

(71) Applicant: Siemens Healthcare GmbH, Erlangen (DE)

(72) Inventors: David Grodzki, Erlangen (DE); Michael Köhler, Nürnberg (DE)

(21) Appl. No.: 18/076,724

(22) Filed: Dec. 7, 2022

(30) Foreign Application Priority Data
Dec. 10, 2021 (EP) 21213584.2

(51) Int. Cl. G01R 33/565; G01R 33/385

(52) U.S. Cl. CPC G01R 33/56518; G01R 33/385

(57) ABSTRACT

Methods for automatically compensating eddy currents in a magnetic resonance apparatus include determining modified magnetic resonance sequence data by a compensation computing unit and performing a magnetic resonance measurement in which a gradient generating system generates magnetic field gradients based on the modified magnetic resonance sequence data. The determining of the modified magnetic field gradient includes: receiving original magnetic resonance sequence data of a predetermined magnetic resonance sequence; computing eddy current information about eddy currents that would be produced in the magnetic resonance apparatus by applying the original magnetic resonance sequence data; computing, based on the computed eddy current information, at least one eddy current compensation gradient pulse for compensating the eddy currents; generating modified magnetic resonance sequence data by inserting the at least one eddy current compensation gradient pulse into the original magnetic resonance sequence data; and outputting the modified magnetic resonance sequence data to the gradient generating system.

The present patent document claims the benefit of European Patent Application No. 21213584.2, filed Dec. 10, 2021, which is hereby incorporated by reference in its entirety.

### TECHNICAL FIELD

The disclosure relates to a method for automatically compensating eddy currents in a magnetic resonance apparatus, to a compensation computing unit, to a magnetic resonance apparatus, and to a computer program product for performing the method.

### BACKGROUND

In medical technology, high soft-tissue contrasts are a particular feature of imaging using magnetic resonance (MR), also known as magnetic resonance imaging (MRI) or magnetic resonance tomography (MRT). This involves using a magnetic resonance apparatus to radiate magnetic resonance sequences, in particular radiofrequency (RF) pulses for generating an RF field, into an examination region, in which a patient is located. This triggers spatially encoded magnetic resonance signals in the patient. The magnetic resonance signals are received as measurement data by the magnetic resonance apparatus and used to reconstruct magnetic resonance images.

For spatial encoding of the magnetic resonance signals, a (mostly linear) magnetic field gradient (e.g., called a “gradient field” or “gradient” for short) may be superimposed on a homogeneous main magnetic field to provide a spatial variation in the resultant total magnetic field or in the Larmor frequency associated therewith.

In an optimum situation, the gradient field only has components along the main magnetic field (e.g. in the z-direction) and may also be adjusted precisely in time. This optimum situation may not be achieved, however, in practice because of Maxwell terms, i.e., components of the gradient field in the x- and/or y-direction, and eddy currents. Eddy currents are generated by time-varying magnetic fields, in particular by ramps of gradient pulses. In order to avoid eddy currents, longer effective repetition times are chosen, for example, so that eddy currents may decay in the “breaks” before the next repetition. This may lead to longer measurement times, however, and sometimes requires the magnetic resonance sequence to be adapted specifically.

### SUMMARY AND DESCRIPTION

The object of the present disclosure may be considered to be to define a method for avoiding eddy current artifacts in imaging magnetic resonance measurements in a straightforward, in particular sequence-independent, manner.

The scope of the present disclosure is defined solely by the appended claims and is not affected to any degree by the statements within this summary. The present embodiments may obviate one or more of the drawbacks or limitations in the related art.

A method, in particular a computer-implemented method, is accordingly proposed for automatically compensating eddy currents in a magnetic resonance apparatus. In this method, modified magnetic resonance sequence data is determined by a compensation computing unit of the magnetic resonance apparatus. The compensation computing unit is an intermediate layer of the magnetic resonance apparatus. In addition, a magnetic resonance measurement is carried out. In this process, a gradient generating system of the magnetic resonance apparatus generates magnetic field gradients, in particular eddy current compensation gradient pulses, in the magnetic resonance apparatus on the basis of the modified magnetic resonance sequence data.

The modified magnetic resonance sequence data is determined as follows. The compensation computing unit receives, (e.g., from a system control unit), original magnetic resonance sequence data of a predetermined magnetic resonance sequence. The compensation computing unit computes eddy current information about (original) eddy currents, which eddy currents would be produced in the magnetic resonance apparatus by applying the original magnetic resonance sequence data if no countermeasures taken were taken. The eddy current information may include the intensity and/or the shape and/or the duration and/or the profile and/or another attribute that characterizes the eddy currents (to be compensated). In addition, the compensation computing unit computes from this eddy current information at least one eddy current compensation gradient pulse for compensating the eddy currents (to be compensated). The compensation computing unit generates modified magnetic resonance sequence data by inserting the at least one eddy current compensation gradient into the original magnetic resonance sequence data. Additionally, the compensation computing unit outputs the modified magnetic resonance sequence data to the gradient generating system, in particular to a gradient control unit of the gradient generating system, of the magnetic resonance apparatus.

Simple and automated eddy current compensation may be achieved by the compensation computing unit acting as an intermediate layer, in particular between a system control unit and the gradient generating system. Advantageously, this may be done independently of the type and/or class of the predetermined magnetic resonance sequence. The intermediate layer may be in the form of software and/or hardware. In particular, the intermediate layer may act as a “black box.”

The magnetic resonance sequence data may include control commands for applying by the magnetic resonance apparatus a series of sequence modules, for instance gradient pulses (for generating magnetic field gradients) and/or RF pulses. For example, a magnetic field gradient may be generated by one or more gradient coils of a gradient coil unit of the gradient generating system. An RF pulse may be generated, for example, by one or more transmit coils of a radiofrequency antenna unit. In particular, the magnetic resonance sequence data may be part of a measurement protocol.

The compensation computing unit may include one or more processors in order to be able to carry out the computations. The compensation computing unit may include one or more interfaces in order to be able to receive the original magnetic resonance sequence data and/or output the modified magnetic resonance sequence data.

The computing of the eddy currents may include computing eddy currents that have accumulated in particular over time during a run-through of the predetermined magnetic resonance sequence.

The intensity of the eddy currents may be computed using, (e.g., solely using), decay constants or time constants. This computation may be performed regardless of the spatial variation of the eddy currents.

Eddy currents may be generated by time-varying magnetic fields, in particular by ramps of gradient pulses. After the ramp of a gradient pulse, an exponential decay of the magnetic field generated thereby may be assumed (as a simplification):

B_{EC}(t)=GA exp(−t/τ)

where B_{EC}(t) denotes the magnetic field generated by the eddy current, G denotes the gradient amplitude after the end of the ramp, A denotes a proportionality constant, t denotes the time, and τ denotes a decay constant of this eddy current.

It has been assumed for this equation that the decay constant is long compared with the ramp duration of the generating gradient, and therefore the amplitude of the eddy current at the end of the ramp is proportional to the gradient amplitude.

Determining the modified magnetic resonance sequence data by the compensation computing unit may include analyzing the gradient profiles of the original magnetic resonance sequence data. Eddy-current induced field perturbations may be computed by modeling and/or a filter function.

The eddy currents may be computed based on at least one parameter specific to a type of the magnetic resonance apparatus. For example, the filter function may be specific to the magnetic resonance apparatus, in particular to the type of the magnetic resonance apparatus. In particular, the filter function may include at least one decay constant τ. In particular, the above-described exponential decrease in the eddy current generated by a gradient ramp may serve as the basis therefor.

In the end, the eddy currents are compensated by the output of a gradient, which in turn generates eddy currents. This gradient therefore generates eddy currents of the reverse polarity in order to compensate these “accumulated” eddy currents. There is no need to compute the spatial distribution thanks to the fact that this compensation gradient again generates the same spatial distribution of eddy currents as the preceding gradients of the sequence.

Magnetic resonance signals may be generated during the magnetic resonance measurement, which are received and analyzed by the magnetic resonance apparatus. This may involve reconstructing one or more magnetic resonance images from the magnetic resonance signals. Spatial information is advantageously imprinted on the magnetic resonance signals by applying the magnetic field gradients by gradient pulses.

The at least one eddy current compensation gradient pulse may be configured to generate compensation eddy currents that are suitable for canceling out some or all of the eddy-current induced field perturbations that would otherwise occur without modification of the magnetic resonance sequence data as a result of the eddy currents to be compensated. The at least one eddy current compensation gradient pulse may have an opposite polarity to the amplitude of preceding magnetic field gradients according to the original magnetic resonance sequence data, which amplitude is averaged over a certain time period. Eddy current compensation is particularly advantageous especially in the case of low field strengths of the main magnetic field, in which impacts of eddy currents are particularly large because of the small absolute frequency difference between fat and water.

The original magnetic resonance sequence data is in particular data that does not take into account any eddy current effects in the magnetic resonance measurement. The original magnetic resonance sequence data advantageously represents any magnetic resonance sequences. Advantageously, there is no need to take account of potentially occurring eddy currents when producing the original magnetic resonance sequence data.

The proposed method for automatically compensating eddy currents is advantageous in particular when the gradient scheme, in particular the series of magnetic field gradients, changes in different parts of the predetermined magnetic resonance sequence. A fixed, single pre-computation of any eddy current compensation gradient pulses is then complex and/or error-prone. By virtue of the proposed dynamic and automatic determination of the modified magnetic resonance sequence data, however, it is possible to adapt the original magnetic resonance sequence data flexibly.

The modified magnetic resonance sequence data may be determined at least in part during the magnetic resonance measurement. In particular, the modified magnetic resonance sequence data is determined in real time and/or on-the-fly. “On-the-fly” may mean dispensing with permanent or temporary storage of data, in particular of the modified magnetic resonance sequence data.

In particular, the modified magnetic resonance sequence data is determined repeatedly and/or continuously while the magnetic resonance measurement is being carried out. Thus determining the modified magnetic resonance sequence data is not done just once, for instance at the start of, or before, the magnetic resonance measurement. In particular, other original magnetic resonance sequence data, in particular occurring successively in the predetermined magnetic resonance sequence, is repeatedly provided to the compensation computing unit for determining further modified magnetic resonance sequence data. For example, the predetermined magnetic resonance sequence is divided into different sequence segments, where each sequence segment has original magnetic resonance sequence data, and this original magnetic resonance sequence data is continuously modified during the magnetic resonance measurement by determining the modified magnetic resonance sequence data, and output as modified magnetic resonance sequence data to the gradient generating system of the magnetic resonance apparatus.

The method for automatically compensating eddy currents may advantageously be applied to every sequence type. The method procedure advantageously does not have to be adapted from one sequence type to another. In particular, there is no need for a sequence-specific implementation of an eddy-current correction, but instead a generalized sequence-independent computation takes place.

According to a further embodiment of the method, the original magnetic resonance sequence data of the predetermined magnetic resonance sequence is provided from a system control unit of the magnetic resonance apparatus. The original magnetic resonance sequence data of the predetermined magnetic resonance sequence may remain unchanged in the control unit in this process. For example, the providing of the original magnetic resonance sequence data may be initiated by, for instance, an operator of the magnetic resonance apparatus setting any predetermined magnetic resonance sequence and starting the magnetic resonance measurement.

The system control unit is in particular a unit that is upstream of the intermediate layer in a signal path to the gradient generating system. The intermediate layer may be inserted in the signal path. This may be done by using logic connections between components of the magnetic resonance apparatus. The intermediate layer may include software and/or hardware. Such software may contain, in particular, program instructions to allow the intermediate layer to acquire, collect, transmit and/or receive the original magnetic resonance sequence data, for instance from a system control unit of the magnetic resonance apparatus and/or from a memory and/or from an analog-to-digital converter and/or from other software of the magnetic resonance apparatus.

The original magnetic resonance sequence data may include image acquisition parameters, image acquisition commands and/or control commands for controlling the magnetic resonance apparatus. The compensation computing unit may determine the modified magnetic resonance sequence data in particular in real time. The original magnetic resonance sequence data itself may remain unchanged, (although modified magnetic resonance sequence data is determined and output), the original magnetic resonance sequence data in the upstream signal path remains unaffected thereby.

The predetermined magnetic resonance sequence may include a diffusion-weighted imaging (DWI) sequence.

Whereas, for instance, turbo-echo based sequences may have a comparatively simple repetitive structure, and therefore in this case the eddy current compensation gradient pulses may also be computed once for a measurement and would not have to be adapted in every repetition, in DWI sequences the eddy currents are dominated by the diffusion gradients, which change in every repetition. The flexible compensation of eddy currents proposed here is therefore particularly advantageous.

According to a further embodiment of the proposed method, determining the modified magnetic resonance sequence data includes detecting at least one fat saturation pulse in the original magnetic resonance sequence data, wherein an eddy current compensation gradient is inserted into the original magnetic resonance sequence data before the at least one fat saturation pulse. Fat saturation pulses may be emitted at the beginning of a repetition of the magnetic resonance sequence. The eddy current compensation gradient is advantageously inserted at the end of the preceding repetition.

The detection of at least one fat saturation pulse may exploit the fact that RF pulses for chemical fat saturation may be off-resonant, i.e., they have a different frequency from (most of) the other RF pulses of the predetermined magnetic resonance sequence. This altered frequency is therefore applied to excite or saturate selectively the fat protons, which have a different resonant frequency from water protons.

In particular, eddy currents that have time constants >10 microseconds (ms) may upset especially the spectral fat saturation as a result of the field perturbations induced by the eddy currents in certain magnetic resonance sequences. Therefore, it is particularly effective to compensate eddy currents in this case.

The predetermined magnetic resonance sequence may be configured to apply gradient pulses to a plurality of axes of the gradient generating system, in particular of the gradient coil unit, wherein the computing of the at least one eddy current compensation gradient pulse takes into account all the gradient pulses so far applied in the magnetic resonance measurement to the plurality of axes of the gradient generating system of the magnetic resonance apparatus.

All the gradient trajectories previously run through on the individual axes in the magnetic resonance measurement may be taken into account. Advantageously, for the algorithm for determining the modified magnetic resonance sequence data it is irrelevant in which repetition, or after which DWI block, it is located, because all these gradient pulses have been captured previously in the computation. The at least one eddy current compensation gradient pulse may be configured such that the generated eddy currents compensate in full or in part the eddy-current induced field perturbations already present.

According to a further embodiment of the proposed method, determining the modified magnetic resonance sequence data includes estimating a magnetic field perturbation that would be produced in the magnetic resonance apparatus by the eddy currents when applying the original magnetic resonance sequence data, wherein an eddy current compensation gradient pulse is computed and inserted into the original magnetic resonance sequence data only when the magnetic field perturbation exceeds a specified threshold value.

For example, it may be specified according to the application up to what proportion (e.g. 50%, or up to a certain defined tolerable field perturbation), the existing field perturbations are compensated. In particular, this may reduce the necessary duration and/or the required amplitude of the eddy current compensation gradient pulse.

According to a further embodiment of the proposed method, determining the modified magnetic resonance sequence data includes identifying in the original magnetic resonance sequence data a time segment in which the magnetic resonance apparatus does not switch any gradient pulses or transmit any RF pulses, wherein the at least one eddy current compensation gradient pulse is inserted into the original magnetic resonance sequence data in the identified time segment. This may advantageously provide that there is no need to change the timing of the magnetic resonance sequence.

The original magnetic resonance sequence data may have at least one dedicated placeholder for the insertion of computed eddy current compensation gradient pulses. Once again, this may provide that there is no need to change the timing of the magnetic resonance sequence. The placeholders may be flagged as such by a flag, for example, whereby the advantageous position would also be specified directly. This may dispense with a potentially more complicated identification of breaks.

A compensation computing unit for determining modified magnetic resonance sequence data of a magnetic resonance measurement by a magnetic resonance apparatus is also proposed. In addition, a magnetic resonance apparatus is proposed having a compensation computing unit as an intermediate layer. The compensation computing unit or the magnetic resonance apparatus is configured to perform a previously described method. The advantages of the compensation computing unit or of the magnetic resonance apparatus are similar to the advantages detailed above of the presented method for automatically compensating eddy currents in a magnetic resonance apparatus.

A computer program product is also proposed, which includes a program and may be loaded directly into a memory of a programmable compensation computing unit of a magnetic resonance apparatus, and has program functions, e.g. libraries and auxiliary functions, in order to determine modified magnetic resonance sequence data when the computer program product is executed in the compensation computing unit of the magnetic resonance apparatus. The computer program product may include software containing a source code, which still needs to be compiled and linked or just needs to be interpreted, or an executable software code, which for execution only needs to be loaded into the compensation computing unit. The method may be performed quickly, reproducibly, and robustly by the computer program product.

The computer program product is configured such that it may be used to perform the method acts according to the disclosure. The compensation computing unit includes the necessary specifications, (e.g., a suitable RAM, a suitable graphics card, or a suitable logic unit), in order to be able to perform the respective method acts efficiently. The computer program product is stored, for example, on a computer-readable medium or on a network or server, from where it may be loaded into the processor of a local compensation computing unit, which processor may be connected directly to the magnetic resonance apparatus or may form part of the magnetic resonance apparatus.

In addition, control data of the computer program product may be stored on an electronically readable data storage medium. The control data in the electronically readable data storage medium may be embodied such that it performs the method disclosed herein when the data storage medium is used in a compensation computing unit of a magnetic resonance apparatus. Examples of electronic readable data storage media are a DVD, a magnetic tape, or a USB stick, on which is stored electronically readable control data, in particular software. When this control data is read from the data storage medium and stored in a compensation computing unit of the magnetic resonance apparatus, all the embodiments of the above-described methods may be performed. Hence, the disclosure may also proceed from the computer-readable medium and/or from the electronically readable data storage medium.

### BRIEF DESCRIPTION OF THE DRAWINGS

Further advantages, features, and details of the disclosure appear in the exemplary embodiments described below and follow from the drawings. Corresponding parts are denoted by the same reference signs in all the figures, in which:

FIG. 1 is a schematic diagram of an example of a magnetic resonance apparatus.

FIG. 2 is a flow diagram of an example of a proposed method.

FIG. 3 is a sequence diagram containing an example of an inserted eddy current compensation gradient pulse.

### DETAILED DESCRIPTION

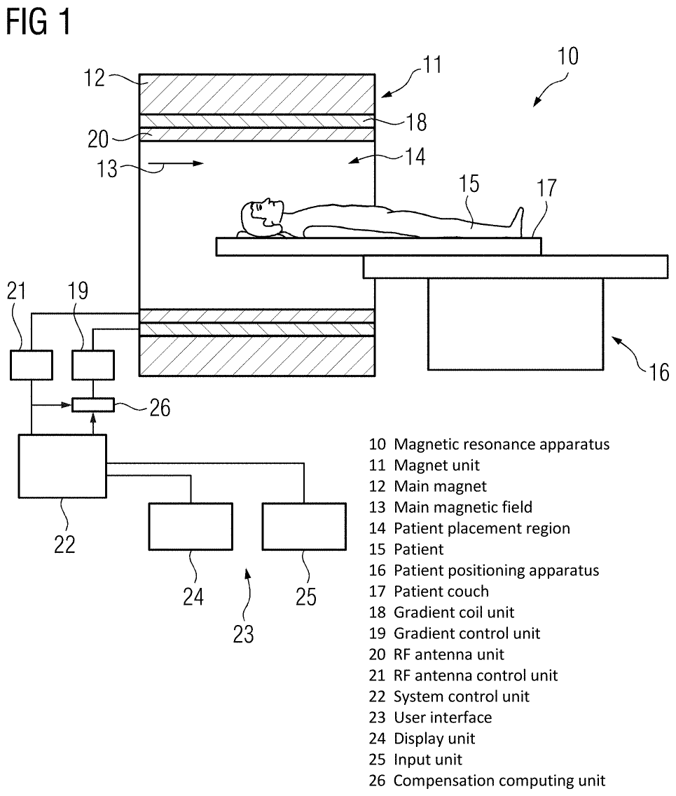

FIG. 1 shows schematically a magnetic resonance apparatus 10. The magnetic resonance apparatus 10 includes a magnet unit 11, which contains a main magnet 12 for generating a powerful main magnetic field 13, which in particular is constant over time. The magnetic resonance apparatus 10 also includes a patient placement region 14 for accommodating a patient 15. In the present exemplary embodiment, the patient placement region 14 is shaped as a cylinder and is enclosed in a circumferential direction cylindrically by the magnet unit 11. In principle, however, it is conceivable that the patient placement region 14 has a different design. The patient 15 may be moved into the patient placement region 14 by a patient positioning apparatus 16 of the magnetic resonance apparatus 10. The patient positioning apparatus 16 includes for this purpose a patient couch 17, which is configured to be able to move inside the patient placement region 14.

The magnet unit 11 further includes a gradient coil unit 18 for generating magnetic field gradients, which are used for spatial encoding during imaging. The gradient coil unit 18 is controlled by a gradient control unit 19 of the magnetic resonance apparatus 10. The gradient coil unit 18 and the gradient control unit 19 are parts of a gradient generating system. The magnet unit 11 also includes a radiofrequency antenna unit 20, which in the present exemplary embodiment is in the form of a body coil that is fixedly integrated in the magnetic resonance apparatus 10. The radiofrequency antenna unit 20 is controlled by a radiofrequency antenna control unit 21 of the magnetic resonance apparatus 10 and radiates magnetic resonance sequences into an examination space, which is formed by a patient placement region 14 of the magnetic resonance apparatus 10. Excitation of atomic nuclei thereby occurs in the main magnetic field 13 produced by the main magnet 12. Magnetic resonance signals are generated by relaxation of the excited atomic nuclei. The radiofrequency antenna unit 20 is configured to receive the magnetic resonance signals. The radiofrequency antenna unit 20 and the radiofrequency antenna control unit 21 are parts of a radiofrequency generating system.

The magnetic resonance apparatus 10 includes a system control unit 22 for controlling the main magnet 12, the gradient control unit 19 and the radiofrequency antenna control unit 21. The system control unit 22 centrally controls the magnetic resonance apparatus 10, for instance in particular implementing a predetermined magnetic resonance sequence, for example, a gradient echo sequence. In addition, the system control unit 22 includes an analysis unit (not presented in further detail) for analyzing the magnetic resonance signals acquired during the magnetic resonance examination. In addition, the magnetic resonance apparatus 10 includes a user interface 23, which is connected to the system control unit 22. Control data such as imaging parameters, for instance, and reconstructed magnetic resonance images may be displayed to medical personnel on a display unit 24, (e.g., at least one monitor), of the user interface 23. In addition, the user interface 23 includes an input unit 25, which may be used by the medical operating personnel to enter data and/or parameters during a measurement procedure.

Between the system control unit 22 and the gradient control unit 19 is a compensation computing unit 26 arranged as an intermediate layer for automatically compensating eddy currents. The compensation computing unit 26 may include both hardware and software elements. Any data, in particular magnetic resonance sequence data of a predetermined magnetic resonance sequence, may be provided from the system control unit 22 of the magnetic resonance apparatus 10 to the compensation computing unit 26, without this data being modified in any way in the control unit 22.

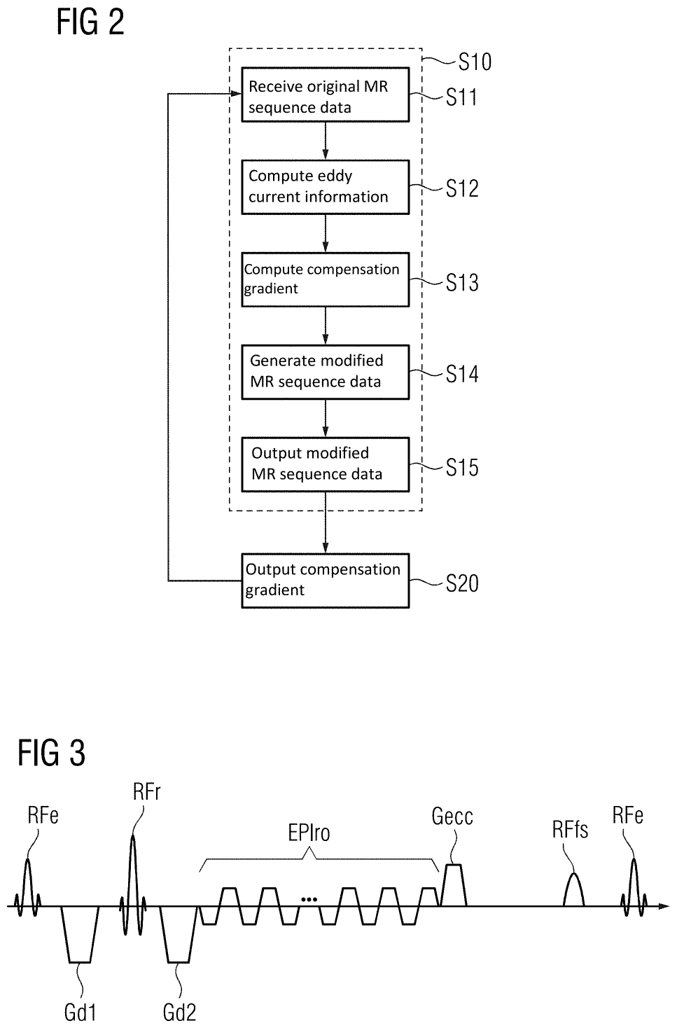

The compensation computing unit 26 is integrated in modular form in the magnetic resonance apparatus 10. The compensation computing unit 26 may be configured such that on removing the compensation computing unit 26 from the magnetic resonance apparatus 10, the gradient generating system may continue to be operated without further limitations apart from the then missing eddy current compensation. FIG. 2 shows a corresponding method for automatically compensating eddy currents in the magnetic resonance apparatus 10. In S10, the compensation computing unit 26 determines modified magnetic resonance sequence data.

S10 includes a plurality of acts for this purpose. In S11, the system control unit 22 receives original magnetic resonance sequence data of a predetermined magnetic resonance sequence. This magnetic resonance sequence may include different sequence modules. The sequence modules may include RF pulses, which are output by the radiofrequency generating system, and/or gradient pulses, which are output by the gradient generating system. The system control unit 22 and/or the compensation computing unit 26 have suitable interfaces for transferring the magnetic resonance sequence data.

In S12, eddy current information about eddy currents that would be produced in the magnetic resonance apparatus by applying the original magnetic resonance sequence data is computed in the compensation computing unit 26.

In particular, the accumulated eddy currents during the run-through of the predetermined magnetic resonance sequence, i.e., during the magnetic resonance measurement, are computed and/or tracked. This is done, for example, by analyzing the gradient profiles of the received original magnetic resonance sequence data and computing the eddy-current induced field perturbations as well using modeling and the filter functions (e.g. decay constants of eddy currents) that are known for the type of the magnetic resonance apparatus 10. An exponential decay of the eddy currents generated by a gradient ramp may serve as the basis therefor, as has been described already above.

The accumulation of the eddy currents for computing the eddy current information involves in particular an accumulation over time. The computing of the intensity of the eddy currents may be performed solely using decay constants or time constants, regardless of the spatial variation. In the end, the eddy currents are compensated by the output of the eddy current compensation gradient pulse, which in turn generates eddy currents. This eddy current compensation gradient pulse advantageously generates eddy currents of the reverse polarity in order to compensate the accumulated eddy currents. Advantageously, there is no need to compute the spatial distribution thanks to the fact that this eddy current compensation gradient pulse may generate the same spatial distribution of eddy currents as the original gradients of the sequence.

In S13, at least one eddy current compensation gradient for compensating the eddy currents is computed on the basis of the eddy current information computed in S12.

In particular, when the event or sequence module to be output next in the magnetic resonance sequence data is a fat saturation pulse (which may be detected really easily from the frequency of the fat saturation pulse, for instance), an eddy current compensation gradient pulse is computed automatically, e.g., taking into account all the gradient trajectories previously run through in the measurement on the individual axes. For the algorithm, it is irrelevant here in which repetition, or after which DWI block, it is located, because all these magnetic field gradients have been captured previously in the computation.

The eddy current compensation gradient pulse is advantageously designed here such that the compensation eddy currents it generates compensates in full or in part the eddy-current induced field perturbations already present. In particular, it may also be specified, for example, up to what proportion (e.g., 50% or up to a certain defined tolerable field perturbation), the existing field perturbations are compensated. In particular, this may reduce the necessary duration and/or the required amplitude of the eddy current compensation gradient pulse.

In S14, modified magnetic resonance sequence data is generated by inserting the eddy current compensation gradient pulse into the original magnetic resonance sequence data. Thus selective intervention and adaptation compared with the original gradient profile of the sequence is performed in order to achieve eddy current compensation.

This may involve identifying in the original magnetic resonance sequence data a time segment in which the magnetic resonance apparatus does not apply any sequence modules, in particular does not switch any gradient pulses or transmit any RF pulses. The eddy current compensation gradient pulse is then inserted into the original magnetic resonance sequence data in the identified time segment.

Advantageously, the eddy current compensation gradient pulse is inserted into a “break” in the sequence, so that the timing of the sequence does not have to be changed. No sequence modules other than the eddy current compensation gradient pulse may be output in this “break.” This is illustrated using an example shown in FIG. 3.

This figure shows a time series of a segment of a magnetic resonance sequence, more precisely of an echo planar (EPI) DWI sequence. The original magnetic resonance data includes here an RF excitation pulse RFe, a first diffusion gradient pulse Gd1, an RF refocusing pulse RFr, and a second diffusion gradient pulse Gd2, followed by a plurality of sequence modules of an EPI readout EPIro, and by an RF fat saturation pulse RFfs, finally followed again by an RF excitation pulse RFe. In S14, it is detected that no sequence modules are applied between the end of the EPI readout EPIro and the fat saturation pulse RFfs. In addition, it may also be detected that the sequence module RFfs is a fat saturation pulse. The eddy current compensation gradient Gecc computed in S13 is now inserted in this “empty” time segment before the fat saturation pulse RFfs, resulting then in the modified magnetic resonance sequence data.

It is proposed as an option that the predetermined magnetic resonance sequence may keep dedicated placeholders for the eddy current compensation gradient pulse, at the position of which the eddy current compensation gradient may be inserted. These placeholders may be flagged as such by a flag, for example, whereby the advantageous position would also be specified directly, and it would be possible to dispense with the previously described identification of suitable time segments.

In S15, the modified magnetic resonance sequence data is output to the gradient generating system, in particular to the gradient control unit 19, of the magnetic resonance apparatus 10. The gradient control unit 19 in turn controls the radiofrequency antenna unit 20 and outputs, in S20, the eddy current compensation gradient Gecc in accordance with the modified magnetic resonance sequence data.

The adaptation shown in FIG. 2 of the predetermined magnetic resonance sequence is advantageously performed at least in part in real time and/or on-the-fly during the magnetic resonance measurement, indicated by the arrow between S20 and S11. Thus, the latest original magnetic resonance sequence data of the predetermined magnetic resonance sequence is continuously provided to the compensation computing unit 26, which data is then modified in S10. This modification is advantageously performed in an automated manner and independently of the sequence type of the predetermined magnetic resonance sequence.

A fundamental advantage of the proposed method is that it is independent of the specific sequence or the sequence type. Advantageously, the method is implemented and managed just once centrally, while no changes, or only minimal changes, are needed in the sequences.

Finally, it should be reiterated that the methods described in detail above and the presented compensation computing unit and magnetic resonance apparatus are merely exemplary embodiments, which may be modified by a person skilled in the art in many ways without departing from the scope of the disclosure. In addition, the use of the indefinite article “a” or “an” does not rule out the possibility of there also being more than one of the features concerned. Likewise, the term “unit” does not exclude the possibility that the components in question include a plurality of interacting sub-components, which may also be spatially distributed if applicable.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the disclosure has been illustrated and described in detail with the help of the embodiments, the disclosure is not limited to the disclosed examples. Other variations may be deduced by those skilled in the art without leaving the scope of protection of the claimed disclosure.

1. A method for automatically compensating eddy currents in a magnetic resonance apparatus, the method comprising:
determining a modified magnetic resonance sequence data by a compensation computing unit as an intermediate layer of the magnetic resonance apparatus; and
performing a magnetic resonance measurement in which a gradient generating system generates magnetic field gradients in the magnetic resonance apparatus based on the modified magnetic resonance sequence data,
wherein the determining of the modified magnetic resonance sequence data comprises:
receiving original magnetic resonance sequence data of a predetermined magnetic resonance sequence;
computing eddy current information about eddy currents that would be produced in the magnetic resonance apparatus by applying the original magnetic resonance sequence data;
computing, based on the computed eddy current information, at least one eddy current compensation gradient pulse for compensating the eddy currents;
generating the modified magnetic resonance sequence data by inserting the at least one eddy current compensation gradient pulse into the original magnetic resonance sequence data; and
outputting the modified magnetic resonance sequence data to the gradient generating system of the magnetic resonance apparatus.

2. The method of claim 1, wherein the modified magnetic resonance sequence data is determined at least in part during the magnetic resonance measurement.

3. The method of claim 2, wherein the modified magnetic resonance sequence data is determined in real time and/or on-the-fly.

4. The method of claim 3, wherein the original magnetic resonance sequence data of the predetermined magnetic resonance sequence is provided from a system control unit of the magnetic resonance apparatus, and
wherein the original magnetic resonance sequence data of the predetermined magnetic resonance sequence remains unchanged in the system control unit.

5. The method of claim 4, wherein the predetermined magnetic resonance sequence comprises a diffusion-weighted sequence.

6. The method of claim 5, wherein the eddy currents are computed based on at least one parameter specific to a type of the magnetic resonance apparatus.

7. The method of claim 1, wherein the modified magnetic resonance sequence data is determined in real time and/or on-the-fly.

8. The method of claim 1, wherein the original magnetic resonance sequence data of the predetermined magnetic resonance sequence is provided from a system control unit of the magnetic resonance apparatus, and
wherein the original magnetic resonance sequence data of the predetermined magnetic resonance sequence remains unchanged in the system control unit.

9. The method of claim 1, wherein the predetermined magnetic resonance sequence comprises a diffusion-weighted sequence.

10. The method of claim 1, wherein the eddy currents are computed based on at least one parameter specific to a type of the magnetic resonance apparatus.

11. The method of claim 1, wherein the determining of the modified magnetic resonance sequence data comprises detecting at least one fat saturation pulse in the original magnetic resonance sequence data, and
wherein the at least one eddy current compensation gradient pulse is inserted into the original magnetic resonance sequence data before the at least one fat saturation pulse.

12. The method of claim 11, wherein the predetermined magnetic resonance sequence comprises applying gradient pulses to a plurality of axes of the gradient generating system of the magnetic resonance apparatus, and
wherein the computing of the at least one eddy current compensation gradient pulse takes into account the gradient pulses so far applied in the magnetic resonance measurement to the plurality of axes of the gradient generating system of the magnetic resonance apparatus.

13. The method of claim 1, wherein the predetermined magnetic resonance sequence comprises applying gradient pulses to a plurality of axes of the gradient generating system of the magnetic resonance apparatus, and
wherein the computing of the at least one eddy current compensation gradient pulse takes into account the gradient pulses so far applied in the magnetic resonance measurement to the plurality of axes of the gradient generating system of the magnetic resonance apparatus.

14. The method of claim 1, wherein the determining of the modified magnetic resonance sequence data comprises estimating a magnetic field perturbation that would be produced in the magnetic resonance apparatus by the eddy currents when applying the original magnetic resonance sequence data, and
wherein the at least one eddy current compensation gradient pulse is computed and inserted into the original magnetic resonance sequence data only when the magnetic field perturbation exceeds a specified threshold value.

15. The method of claim 1, wherein the determining of the modified magnetic resonance sequence data comprises identifying in the original magnetic resonance sequence data a time segment in which the magnetic resonance apparatus does not switch any gradient pulses or transmit any radiofrequency (RF) pulses, and
wherein the at least one eddy current compensation gradient pulse is inserted into the original magnetic resonance sequence data in the identified time segment.

16. The method of claim 1, wherein the original magnetic resonance sequence data has at least one dedicated placeholder for the inserting of computed eddy current compensation gradient pulses.

17. A compensation computing unit for determining modified magnetic resonance sequence data for performing a magnetic resonance measurement by a magnetic resonance apparatus, the compensation computing unit comprising:
at least one processor configured to:
receive original magnetic resonance sequence data of a predetermined magnetic resonance sequence;
compute eddy current information about eddy currents that would be produced in the magnetic resonance apparatus by applying the original magnetic resonance sequence data;
compute, based on the computed eddy current information, at least one eddy current compensation gradient pulse for compensating the eddy currents;
generate modified magnetic resonance sequence data by inserting the at least one eddy current compensation gradient pulse into the original magnetic resonance sequence data; and
output the modified magnetic resonance sequence data to a gradient generating system of the magnetic resonance apparatus for performing the magnetic resonance measurement.

18. A magnetic resonance apparatus comprising:
a compensation computing unit,
wherein the magnetic resonance apparatus is configured to:
receive original magnetic resonance sequence data of a predetermined magnetic resonance sequence;
compute eddy current information about eddy currents that would be produced in the magnetic resonance apparatus by applying the original magnetic resonance sequence data;
compute, based on the computed eddy current information, at least one eddy current compensation gradient pulse for compensating the eddy currents;
generate modified magnetic resonance sequence data by inserting the at least one eddy current compensation gradient pulse into the original magnetic resonance sequence data; and
output the modified magnetic resonance sequence data to a gradient generating system of the magnetic resonance apparatus for performing a magnetic resonance measurement.
